(19) United States
(12) Patent Application Publication
(10) Pub. No.: US 2019/0383685 A1
(43) Pub. Date: Dec. 19, 2019

(54) Pressure Sensing Apparatus and Control Method Thereof

(71) Applicant: Tyco Electronics AMP Korea Co., Ltd., Gyungsan-si (KR)

(72) Inventor: Young-Deok Kim, Gyungsan-si (KR)

(73) Assignee: Tyco Electronics AMP Korea Co., Ltd., Gyungsan-si (KR)

(21) Appl. No.: 16/441,279

(22) Filed: Jun. 14, 2019

(30) Foreign Application Priority Data
Jun. 14, 2018 (KR) 10-2018-0068296
May 15, 2019 (KR) 10-2019-0057143

(51) Int. Cl. G01L 9/04; G01R 17/10; G01L 27/00; G01K 7/20; G01L 1/22

(52) U.S. Cl. CPC G01L 9/04; G01R 17/105; G01L 1/22; G01K 7/20; G01L 27/005

(57) ABSTRACT

A pressure sensing apparatus comprising a pressure sensor configured to sense a pressure and a controller. The controller is configured to supply a reverse bias voltage to the pressure sensor or to not supply a bias voltage to the pressure sensor in a time duration in which pressure sensing of the pressure sensor is not performed.

### CROSS-REFERENCE TO RELATED APPLICATIONS

This application claims the benefit of the filing date under 35 U.S.C. § 119(a)-(d) of Korean Patent Application No. 10-2018-0068296, filed on Jun. 14, 2018, and Korean Patent Application No. 10-2019-0057143, filed on May 15, 2019.

### FIELD OF THE INVENTION

The present invention relates to a pressure sensing apparatus and, more particularly, to control of a pressure sensing apparatus.

### BACKGROUND

A Wheatstone bridge circuit is a representative circuit that is used to detect a fine electrical signal. A bridge circuit, such as the Wheatstone bridge circuit, is used to measure a change in, for example, resistance and capacitance. The bridge circuit may be used to output a fine change in, for example, a pressure sensor, a force sensor, and a gravity sensor, as an electrical signal.

A bridge circuit including a strain gauge, for example, may be used to sense a strain of an object by a force applied from an outside. The strain gauge refers to a device of which an electrical resistance varies to be proportional to a magnitude of varying strain of a target object and outputs the measured strain as a change of voltage.

A bridge circuit, for example, may also be used for a pressure sensor to measure the braking hydraulic pressure of a pedal in a brake system of a vehicle. The pressure sensor configured to sense the brake operating pressure generated in a master cylinder in proportion to the brake pedal pressure of a driver may be installed in a hydraulic block within an anti-lock brake system (ABS) configured to electronically control the brake pressure. An electronic control apparatus controls an operation of a brake in response to an electrical signal transmitted from the pressure sensor.

### SUMMARY

A pressure sensing apparatus comprising a pressure sensor configured to sense a pressure and a controller. The controller is configured to supply a reverse bias voltage to the pressure sensor or to not supply a bias voltage to the pressure sensor in a time duration in which pressure sensing of the pressure sensor is not performed.

### BRIEF DESCRIPTION OF THE DRAWINGS

The invention will now be described by way of example with reference to the accompanying Figures, of which:

FIG. 1 is a circuit diagram of a pressure sensing apparatus with a pair of half bridge circuits;

FIG. 2 is a schematic block diagram of a pressure sensing apparatus according to an embodiment;

FIG. 3A is a circuit diagram of a half bridge circuit in a first switch state;

FIG. 3B is a circuit diagram of the half bridge circuit in a second switch state;

FIG. 3C is a circuit diagram of the half bridge circuit in a third switch state; and

FIG. 4 is a flowchart of a method of controlling a pressure sensing apparatus according to an embodiment.

### DETAILED DESCRIPTION OF THE EMBODIMENTS

Hereinafter, some exemplary embodiments will be described in detail with reference to the accompanying drawings. Example embodiments are described below in order to explain the present disclosure by referring to the figures. The following structural or functional descriptions are merely exemplary and the scope of the exemplary embodiments is not limited to the descriptions provided in the present specification. Various changes and modifications can be made thereto by those of ordinary skill in the art. Like numerals refer to like elements throughout and a repeated description related thereto is omitted. Detailed description of well-known related structures or functions will be omitted when it is deemed that such description will cause ambiguous interpretation of the present disclosure.

Although terms of “first” or “second” are used to explain various components, the components are not limited to the terms. These terms should be used only to distinguish one component from another component. As used herein, the singular forms are intended to include the plural forms as well, unless the context clearly indicates otherwise. It should be further understood that the terms “comprises” and/or “comprising,” when used in this specification, specify the presence of stated features, integers, steps, operations, elements, components or a combination thereof, but do not preclude the presence or addition of one or more other features, integers, steps, operations, elements, components, and/or groups thereof.

Unless otherwise defined herein, all terms used herein including technical or scientific terms have the same meanings as those generally understood by one of ordinary skill in the art. Terms defined in dictionaries generally used should be construed to have meanings matching with contextual meanings in the related art and are not to be construed as an ideal or excessively formal meaning unless otherwise defined herein.

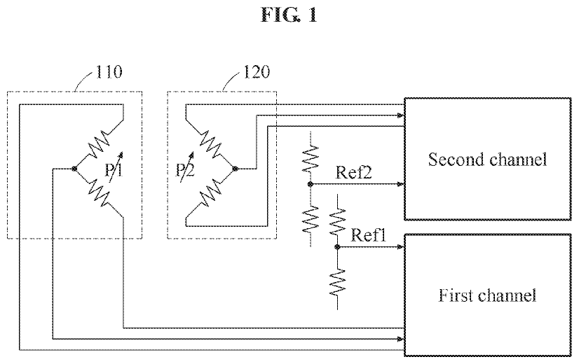

A pressure sensing apparatus including half bridge circuits according to an embodiment is shown in FIG. 1. The pressure sensing apparatus may sense a pressure that is applied to a first half bridge circuit 110 and/or a second half bridge circuits 120 using the corresponding first and/or second half bridge circuits 110 and 120 as a pressure sensor. A resistance value of each of the first and second half bridge circuits 110 and 120 may vary based on the applied pressure and the pressure may be measured based on the resistance value of the first and/or second half bridge circuits 110 and 120. In an embodiment, the first and/or second half bridge circuits 110 and 120 may be provided by attaching a strain gauge to a mechanical structure of a sensor using glass bonding or epoxy bonding.

The first half bridge circuit 110 may form a first channel of a pressure sensor and the second half bridge circuit 120 may form a second channel of the pressure sensor. The first half bridge circuit 110 and the second half bridge circuit 120 may independently operate. A controller included in the pressure sensing apparatus may estimate a magnitude of pressure based on the resistance value of each of the first half bridge circuit 110 and the second half bridge circuit 120.

In an embodiment, the pressure sensing apparatus may further include a temperature sensor, and may correct a sensing value of the pressure sensor based on a temperature value measured through the temperature sensor. The temperature sensor may be provided inside or outside the pressure sensing apparatus. The pressure sensing apparatus may include a circuit to provide reference voltages Ref1 and Ref2, as shown in FIG. 1. In embodiment, the circuit is provided on a printed circuit board (PCB).

In an embodiment, one of the first half bridge circuit 110 and the second half bridge circuit 120 may act as a redundancy circuit. For example, in response to an occurrence of an error in a function of the first half bridge circuit 110 while sensing the pressure using the first half bridge circuit 110, the pressure sensing apparatus may further stably sense the pressure by sensing the pressure using the second half bridge circuit 120. In particular, in a situation in which a pressure value measured by the pressure sensor is directly related to safety, the stability of pressure sensing becomes more important.

The pressure sensing apparatus including the redundancy circuit may be provided with a simple design and a low cost by using the first and second half bridge circuits 110 and 120. In the case of the pressure sensing apparatus using the first and second half bridge circuits 110 and 120, a sensor offset may not be stable in a high temperature environment in response to an operation of the pressure sensor due to an ion-migration phenomenon. For example, the ion-migration phenomenon may occur due to impurities that flow in or are generated during a process of manufacturing the pressure sensing apparatus. The pressure sensing apparatus may use one channel based on one of the first half bridge circuit 110 and the second half bridge circuit 120 for pressure sensing. The other channel may use the reference voltage Ref1 or Ref2. Accordingly, the ion-migration phenomenon may directly apply to a pressure sensing result. A full bridge circuit may include two half bridge circuits having such an issue. Since each half bridge circuit has a similar ion-migration phenomenon, the ion-migration phenomenon may be offset and only a relative deviation of the ion-migration phenomenon is output.

A Wheatstone bridge may be, for example, a full bridge circuit that uses all of four strain gauges, a half bridge circuit that uses two of the four strain gauges and replaces the remaining two strain gauges with fixed resistance, and a quarter bridge circuit that uses only one of the four strain gauges and replaces the remaining three strain gauges with fixed resistance. Here, the full bridge circuit exhibits a relatively excellent product performance and stability, however, requires a relatively large design area and complex manufacturing process.

With compactness, high density, and high integration in the pressure sensor, it would be desirable to achieve the equivalent performance with a simplified design. Further, as a recent trend of the pressure sensor, a redundancy design enables the pressure sensor to maintain the function of the pressure sensor although a product partially malfunctions. If a single pressure sensor channel is designed in a simple structure and is capable of maintaining the performance, it may be useful to design the product to include the redundancy circuit. The two half bridge circuits 110, 120 may be similar to a single full bridge circuit in terms of appearance or a manufacturing process. However, the two half bridge circuits 110, 120 may independently operate while maintaining the respective performance, which may lead to implementing the redundancy circuit.

The following exemplary embodiments relate to a driving and interface method of half bridge circuits such that the performance and the stability of the half bridge circuits 110, 120 may meet the requirements of the full bridge circuit.

In the case of using the half bridge circuits 110, 120, a sensor bridge circuit may not compensate for a degradation in the performance occurring when each individual strain gauge operates during a lifespan cycle of a product. As a solution, such an issue may be fundamentally solved during a process of manufacturing or attaching a strain gauge to prevent the degradation in the performance. Alternatively, a new technique is applied to a sensor bridge interface and driving method to prevent the degradation in the performance under limited conditions, as described in greater detail below.

A portion closest thereto is a long time-drift phenomenon of a resistance value or a resulting voltage output of a strain gauge by an ion present in a bonding layer, that is, an adhesion layer, used to attach each strain gauge onto a surface of a sensor structure and an ion-migration phenomenon of an ionic material. An ionized material present in the bonding layer has a force of moving by an electronic pulling force or pushing force in response to being exposed in an environment in which an electric field is formed. Accordingly, when the ionized material is exposed in a high temperature for long hours, the ionized material may be further active particularly since the ionized material, which is a kind of impurity, may further actively move in a high temperature environment. If an ion migration occurs in reality, the ion migration may change a resistance value of a strain gauge. If the ion migration persists for long time, it may cause an issue in the performance and stability of a product. The full bridge circuit may make a compensation, whereas the half bridge circuits 110, 120 may not generate such a compensation mechanism. Accordingly, there is a need to enhance a driving circuit to prevent an occurrence of the ion-migration phenomenon.

The ion-migration phenomenon occurs in the half bridge circuit 110, 120 when the following two conditions are met.

A first condition is that a sensor bridge is biased, that is, that current flows in the sensor bridge. If current does not flow in the sensor bridge, the ion-migration phenomenon does not occur. When a current direction of the sensor bridge is changed to an opposite direction, the ion-migration phenomenon occurs in the opposite direction. When the current direction is drifted such that an original individual resistance value of the strain gauge increases by the ion-migration phenomenon, and in this instance, the current is changed to flow in the opposite direction, the resistance value is restored to an original state and then continuously progresses to decrease.

A second condition is a temperature condition. Resistance of a strain gauge is relatively stable at a room temperature or at a low temperature and barely varies even for being biased. However, the resistance of the strain gauge further sensitively reacts under a high temperature condition.

The following methods may relieve or solve the above issues when the pressure sensor operates.

1) Initially, power may be supplied to a half bridge circuit 110, 120 only at a moment at which a variance of voltage according to pressure from the sensor bridge is measured. In reality, for pressure measurement using the pressure sensor, it takes a relatively short period of time for a signal processor to amplify a voltage output of a half bridge circuit 110, 120 and for an analog-to-digital converter (ADC) to read a value. During a single loop time of the signal processor, a most of the loop time is used for an idle state or is distributed for a time for detecting a built-in failure. Accordingly, if an amount of time used for the half bridge circuit 110, 120 to be biased is minimized, a resistance value of the strain gauge is drifted by the reduced amount of time due to the ion-migration phenomenon and it is possible to delay a time at which a degradation in performance occurs.

2) As a further aggressive method, a reverse bias voltage is supplied to a half bridge circuit 110, 120 during a remaining idle time to be equivalent to a time duration in which a forward bias voltage is supplied to the half bridge circuit 110, 120 for pressure measurement. Accordingly, it is possible to minimize a degradation in performance by the ion-migration phenomenon. The ion-migration phenomenon or a change in the resistance of the strain gauge thereby occurs slowly over a long period of time. However, a period for measuring an output value of the pressure sensor through the half bridge circuit 110, 120 is relatively very fast. For example, corresponding measurement may be performed 1000 times per second. Also, an output of the half bridge circuit 110, 120 may be measured during a very short period of time, for example, a period of 1/1000 second, and the remaining time may be an idle time. Accordingly, when a time duration in which a reverse bias voltage is supplied is identical to a time duration in which a forward reverse bias voltage is supplied, it is possible to minimize the ion-migration phenomenon.

Hereinafter, a method of designing and controlling a pressure sensing apparatus to outperform an issue by an ion-migration phenomenon will be described in greater detail.

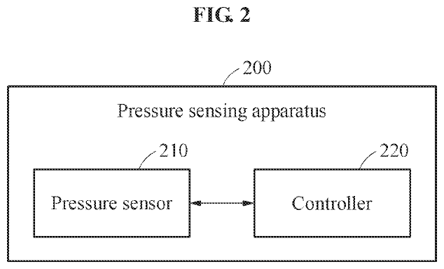

A pressure sensing apparatus 200 according to an embodiment, shown in FIG. 2, include a pressure sensor 210 and a controller 220.

The pressure sensor 210 senses a pressure. The pressure sensor 210 may sense a change in a pressure applied from an outside and may output the change in the pressure as a change in a voltage. The pressure sensor 210 may include a first half bridge circuit and a second half bridge circuit. The first half bridge circuit may form a first channel for pressure sensing and the second half bridge circuit may form a second channel for pressure sensing. The first half bridge circuit and the second half bridge circuit may sense the pressure using a strain gauge, a capacitor, a resistance element, and the like.

The pressure sensing apparatus 200 may sense the pressure using at least one of the first half bridge circuit and the second half bridge circuit. In one example embodiment, when the pressure sensing apparatus 200 senses the pressure using the first half bridge circuit, the second half bridge circuit may act as a redundancy circuit available in a case in which the first half bridge circuit malfunctions.

The controller 220 may control an overall operation of the pressure sensing apparatus 200. The controller 220 may include at least one processor and may be provided in an application specific integrated circuit (ASIC). The controller 220 includes a memory that is a non-transitory computer readable medium.

In an embodiment, the controller 220 determines whether the pressure sensor 210 malfunctions based on an output of the pressure sensor 210. For example, when an output of the pressure sensor 210 is maintained at a low value, for example, zero, or at a high value, for example, an abnormally large value, during a desired period of time, the controller 220 may determine that the sensor malfunctions. Alternatively, when the pressure sensor 210 outputs an unpredicted value during a desired period of time, the controller 220 may determine that the pressure sensor 210 malfunctions. When the controller 220 detects a malfunction in the first channel while sensing the pressure using the first channel, the controller 220 may sense the pressure using the second channel.

In an embodiment, an ion-migration phenomenon may be reduced by increasing a distance between bonding pads that connect elements of half bridge circuits. For example, a distance D between bonding pads may be designed to be greater than or equal to 100 micrometer (μm).

The ion-migration phenomenon may be reduced by setting a voltage of power supplied to the pressure sensor 210 to be small. For example, the controller 220 may reduce the ion-migration phenomenon by supplying a lower voltage than a voltage generally supplied to the pressure sensor 210 and, instead, increasing a signal gain at a signal processing end. To this end, the controller 220 may use a regulator capable of providing a voltage lower than a reference voltage supplied to the pressure sensor 210.

The controller 220 may reduce the ion-migration phenomenon by changing a power supply method for the pressure sensor 210. In one example embodiment, the controller 220 may supply a forward bias voltage to the pressure sensor 210 in a time duration in which pressure sensing of the pressure sensor 210 is performed and may supply a reverse bias voltage to the pressure sensor 210 in a time duration in which pressure sensing of the pressure sensor 210 is not performed. For example, a time duration in which the forward bias voltage is supplied to the pressure sensor 210 may be identical to a time duration in which the reverse bias voltage is supplied to the pressure sensor 210.

In another example embodiment, in a time duration in which the pressure sensor 210 does not perform pressure sensing, for example, in an idle time, the controller 220 may not supply a bias voltage to the pressure sensor 210.

In an embodiment, the controller 220 may use switches to control a power supply method. For example, the pressure sensing apparatus 200 may further include a first switch configured to connect one end of the first half bridge circuit to a first voltage end or a second voltage end, and a second switch configured to connect another end of the first half bridge circuit to the second voltage end or the first voltage end. The first switch and the second switch may be controlled by the controller 220. A first voltage supplied from the first voltage end is greater than a second voltage supplied from the second voltage end.

In a time duration in which the pressure sensor 210 senses a pressure using the first half bridge circuit, the first switch may connect one end of the first half bridge circuit to the first voltage end and the second switch may connect the other end of the first half bridge circuit to the second voltage end. In a time duration in which pressure sensing of the pressure sensor 210 is not performed, the first switch may connect one end of the first half bridge circuit to the second voltage end and the second switch may connect the other end of the first half bridge circuit to the first voltage end.

The pressure sensing apparatus 200 may further include a third switch configured to connect one end of the second half bridge circuit to the first voltage end or the second voltage end and a fourth switch configured to connect another end of the second half bridge circuit to the second voltage end or the first voltage end. The third switch and the fourth switch may be controlled by the controller 220.

Similar to a control method of the first half bridge circuit, in a time duration in which the pressure sensor 210 senses the pressure using the second half bridge circuit, the third switch may connect one end of the second half bridge circuit to the first voltage end and the fourth switch and may connect the other end of the second half bridge circuit to the second voltage end. In a time duration in which pressure sensing of the pressure sensor 210 is not performed, the third switch may connect one end of the second half bridge circuit to the second voltage end and the fourth switch may connect the other end of the second half bridge circuit to the first voltage end.

The controller 220 may alternately repeat a first control of supplying a forward bias voltage to the pressure sensor 210 and a second control of supplying a reverse bias voltage to the pressure sensor 210 or not supplying a bias voltage to the pressure sensor 210. Here, since the first control and the second control are repeatedly performed at short time intervals, a change in the resistance of the pressure sensor 210 may be rebalanced.

Through the control method of the pressure sensing apparatus 200, the ion-migration phenomenon may be reduced and the pressure sensing apparatus 200 may stably operate.

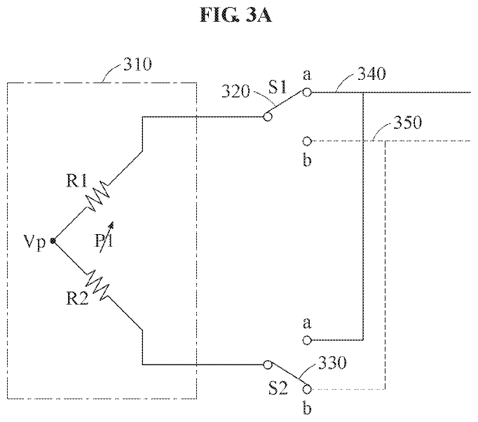

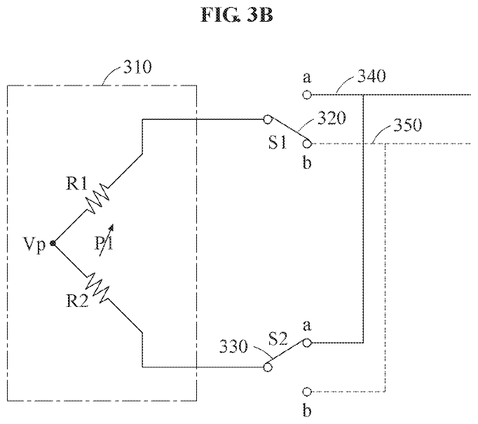

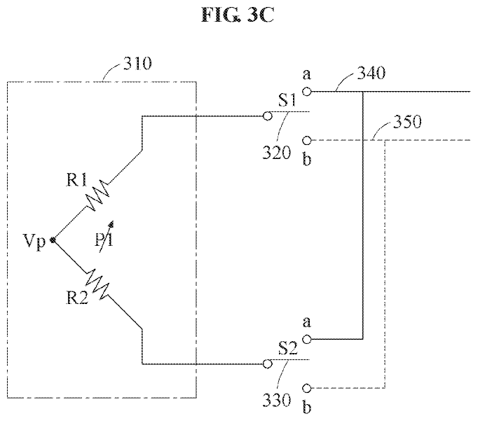

A method of controlling a single half bridge circuit is described with reference to circuit diagrams shown in FIGS. 3A-3C. The following description may apply to other half bridge circuit control methods.

Referring to FIG. 3A, a half bridge circuit 310 may operate per a millisecond (msec) period. In a time duration in which the half bridge circuit 310 senses a pressure, a forward bias voltage is supplied to the half bridge circuit 310. In response thereto, a first switch S1 320 may connect one end of the half bridge circuit 310 to a first voltage end a 340 and a second switch S2 330 may connect another end of the half bridge circuit 310 to a second voltage end b 350. The first switch S1 320 and the second switch S2 330 may be controlled in response to a control signal output from a controller. A first voltage supplied from the first voltage end a 340 may be greater than a second voltage supplied from the second voltage end b 350.

An ion-migration phenomenon may occur in the above time duration. The ion-migration phenomenon may cause a change in a resistance value of the half bridge circuit 310. For example, when the forward bias voltage is supplied to the half bridge circuit 310 and the half bridge circuit 310 is placed in a high temperature environment, a resistance value of a strain gauge R1 may increase and a resistance value of a strain gauge S2 may decrease due to the ion-migration phenomenon. Accordingly, a voltage output of an output end Vp of the half bridge circuit 310 may further decrease compared to a prediction. The ion-migration phenomenon may be further activated in the high temperature environment. When an output value of a pressure sensor is determined to be different from a prediction due to the ion-migration phenomenon and the ion-migration phenomenon continues for a long time, it may cause a great degradation in the performance.

Referring to FIG. 3B, the controller may decrease or prevent the ion-migration phenomenon by supplying a reverse bias voltage to the half bridge circuit 310 in a time duration in which pressure sensing using the half bridge circuit 310 is not performed. Here, the first switch S1 320 may connect one end of the half bridge circuit 310 to the second voltage end b 350 and the second switch S2 330 may connect another end of the half bridge circuit 310 to the first voltage end a 340. Accordingly, a voltage opposite to the forward bias voltage supplied to the half bridge circuit 310 is supplied. In this case, a resistance value of the strain gauge R1 may decrease and a resistance value of the strain gauge R2 may increase, and a voltage output of the output end Vp of the half bridge circuit 310 may further increase compared to a prediction.

The aforementioned time duration in which pressure sensing using the half bridge circuit 310 is not performed may be referred to as an idle time. In the idle time, the reverse bias voltage is controlled to be supplied to the half bridge circuit 310. Accordingly, the ion-migration phenomenon may occur differently from the example of FIG. 3A. In the idle time, an output value of the half bridge circuit 310 may change to be restored to an originally predicted output value.

A first control of supplying the forward bias voltage to the half bridge circuit 310 and a second control of supplying the reverse bias voltage to the half bridge circuit 310 may be alternately repeated. In an embodiment, a time duration in which the first control is performed may be identical to a time duration in which the second control is performed. Since supply of the forward bias voltage and supply of the reverse bias voltage are alternately repeated, it is similar to a case in which the bias voltage is not supplied to the half bridge circuit 310. A degradation in the performance of the half bridge circuit 310 by the ion-migration phenomenon may be prevented or reduced.

Referring to FIG. 3C, in a time duration in which pressure sensing using the half bridge circuit 310 is not performed, the controller may not supply a bias voltage to the half bridge circuit 310. Here, the first switch S1 320 and the second switch S2 330 are not connected to any voltage end.

As described above, in an idle time in which pressure sensing using the half bridge circuit 310 is not performed, the bias voltage is not supplied and thus, it is possible to reduce the ion-migration phenomenon occurring when the forward bias voltage is supplied to the half bridge circuit 310.

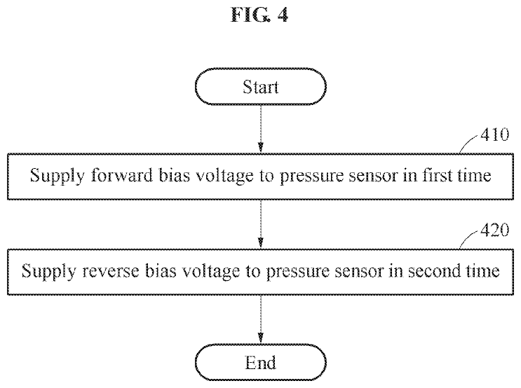

A control method of a pressure sensing apparatus according to an embodiment is shown in FIG. 4. The control method of the pressure sensing apparatus may be performed by a controller included in the pressure sensing apparatus and described above,

As shown in FIG. 4, in operation 410, the controller may control the pressure sensing apparatus to supply a forward bias voltage to a pressure sensor in a first time duration. In the first time duration, pressure sensing of the pressure sensor may be performed.

In an embodiment, the pressure sensor may include a first half bridge circuit and a second half bridge circuit available for pressure sensing. To supply the forward bias voltage to the first half bridge circuit, the controller may connect one end of the first half bridge circuit to a first voltage end and may connect another end of the first half bridge circuit to a second voltage end. Here, a first voltage supplied from the first voltage end may be greater than a second voltage supplied from the second voltage end. Even in the case of supplying the forward bias voltage to the second half bridge circuit, the controller may connect one end of the second half bridge circuit to the first voltage end and may connect another end of the second half bridge circuit to the second voltage end, which is similar to the aforementioned example. The connection between the first or second half bridge circuit and the first or second voltage end may be controlled by a switch.

In operation 420 shown in FIG. 4, the controller may control the pressure sensing apparatus to supply a reverse bias voltage to the pressure sensor in a second time duration. The second time duration may be an idle time in which pressure sensing of the pressure sensor is not performed.

To supply the reverse bias voltage to the first half bridge circuit, the controller may connect one end of the first half bridge circuit to the second voltage end and may connect the other end of the first half bridge circuit to the first voltage end. In the case of supplying the forward bias voltage to the second half bridge circuit, the controller may connect one end of the second half bridge circuit to the second voltage end and may connect the other end of the second half bridge circuit to the first voltage end.

In an embodiment, in the second time duration, the controller may not supply any bias voltage except supplying the reverse bias voltage to the pressure sensor.

Operation 410 that is a first control of supplying the forward bias voltage to the pressure sensor and operation 420 that is the second control of supplying the reverse bias voltage to the pressure sensor or not supplying the bias voltage to the pressure sensor may be alternately repeated at short time intervals. Accordingly, a change in resistance of the pressure sensor may be rebalanced.

The embodiments described herein may be implemented using hardware components, software components, and/or combination thereof. For example, the hardware components may include microphones, amplifiers, band-pass filters, audio to digital convertors, and processing devices. A processing device may be implemented using one or more hardware device configured to carry out and/or execute program code by performing arithmetical, logical, and input/output operations. The processing device(s) may include a processor, a controller and an arithmetic logic unit, a digital signal processor, a microcomputer, a field programmable array, a programmable logic unit, a microprocessor or any other device capable of responding to and executing instructions stored on a non-transitory computer readable medium in a defined manner. The processing device may run an operating system (OS) and one or more software applications that run on the OS. The processing device also may access, store, manipulate, process, and create data in response to execution of the software. For purpose of simplicity, the description of a processing device is used as singular; however, one skilled in the art will appreciated that a processing device may include plurality of processing elements and plurality of types of processing elements. For example, a processing device may include plurality of processors or a processor and a controller. In addition, different processing configurations are possible, such parallel processors.

The software may include a computer program, a piece of code, an instruction, or some combination thereof, to independently or collectively instruct and/or configure the processing device to operate as desired, thereby transforming the processing device into a special purpose processor. Software and data may be embodied permanently or temporarily in any type of non-transitory machine, component, physical or virtual equipment, computer storage medium or device, or in a propagated signal wave capable of providing instructions or data to or being interpreted by the processing device. The software also may be distributed over network coupled computer systems so that the software is stored and executed in a distributed fashion. The software and data may be stored by one or more non-transitory computer readable recording mediums.

The methods according to the above-described example embodiments may be recorded in non-transitory computer-readable media including program instructions to implement various operations of the above-described example embodiments. The media may also include, alone or in combination with the program instructions, data files, data structures, and the like. The program instructions recorded on the media may be those specially designed and constructed for the purposes of example embodiments, or they may be of the kind well-known and available to those having skill in the computer software arts. Examples of non-transitory computer-readable media include magnetic media such as hard disks, floppy disks, and magnetic tape; optical media such as CD-ROM discs, DVDs, and/or Blue-ray discs; magneto-optical media such as optical discs; and hardware devices that are specially configured to store and perform program instructions, such as read-only memory (ROM), random access memory (RAM), flash memory (e.g., USB flash drives, memory cards, memory sticks, etc.), and the like. Examples of program instructions include both machine code, such as produced by a compiler, and files containing higher level code that may be executed by the computer using an interpreter. The above-described devices may be configured to act as one or more software modules in order to perform the operations of the above-described example embodiments, or vice versa.

The foregoing example embodiments are examples and are not to be construed as limiting. The present teaching can be readily applied to other types of apparatuses. Also, the description of the example embodiments is intended to be illustrative, and not to limit the scope of the claims, and many alternatives, modifications, and variations will be apparent to those skilled in the art.

What is claimed is:

1. A pressure sensing apparatus comprising:
a pressure sensor configured to sense a pressure; and
a controller configured to supply a reverse bias voltage to the pressure sensor or to not supply a bias voltage to the pressure sensor in a time duration in which pressure sensing of the pressure sensor is not performed.

2. The pressure sensing apparatus of claim 1, wherein the pressure sensor includes a first half bridge circuit.

3. The pressure sensing apparatus of claim 2, further comprising a first switch configured to connect one end of the first half bridge circuit to a first voltage end or a second voltage end and a second switch configured to connect another end of the first half bridge circuit to the second voltage end or the first voltage end, the first switch and the second switch are controlled by the controller.

4. The pressure sensing apparatus of claim 3, wherein a first voltage supplied from the first voltage end is greater than a second voltage supplied from the second voltage end.

5. The pressure sensing apparatus of claim 4, wherein, in a time duration in which the pressure sensor senses the pressure, the first switch is configured to connect the one end of the first half bridge circuit to the first voltage end and the second switch is configured to connect the another end of the first half bridge circuit to the second voltage end.

6. The pressure sensing apparatus of claim 5, wherein, in the time duration in which pressure sensing of the pressure sensor is not performed, the first switch is configured to connect the one end of the first half bridge circuit to the second voltage end and the second switch is configured to connect the another end of the first half bridge circuit to the first voltage end.

7. The pressure sensing apparatus of claim 2, wherein the pressure sensor includes a second half bridge circuit.

8. The pressure sensing apparatus of claim 7, further comprising a third switch configured to connect one end of the second half bridge circuit to a first voltage end or a second voltage end and a fourth switch configured to connect another end of the second half bridge circuit to the second voltage end or the first voltage end, the third switch and the fourth switch are controlled by the controller.

9. The pressure sensing apparatus of claim 8, wherein a first voltage supplied from the first voltage end is greater than a second voltage supplied from the second voltage end.

10. The pressure sensing apparatus of claim 7, wherein the first half bridge circuit is configured to form a first channel for pressure sensing and the second half bridge circuit is configured to form a second channel for pressure sensing.

11. The pressure sensing apparatus of claim 1, wherein the controller is configured to alternately repeat a first control of supplying a forward bias voltage to the pressure sensor and a second control of supplying the reverse bias voltage to the pressure sensor or not supplying the bias voltage to the pressure sensor.

12. A control method of a pressure sensing apparatus, comprising:
supplying a forward bias voltage to a pressure sensor in a first time duration; and
supplying a reverse bias voltage to the pressure sensor or not supplying a bias voltage to the pressure sensor in a second time duration.

13. The control method of claim 12, wherein pressure sensing of the pressure sensor is performed in the first time duration and pressure sensing of the pressure sensor is not performed in the second time duration.

14. The control method of claim 12, wherein the pressure sensor includes a first half bridge circuit.

15. The control method of claim 14, wherein the supplying of the forward bias voltage comprises connecting one end of the first half bridge circuit to a first voltage end and connecting another end of the first half bridge circuit to a second voltage end.

16. The control method of claim 15, wherein a first voltage supplied from the first voltage end is greater than a second voltage supplied from the second voltage end.

17. The control method of claim 14, wherein the supplying of the reverse bias voltage comprises connecting one end of the first half bridge circuit to a second voltage end and connecting another end of the first half bridge circuit to a first voltage end.

18. The control method of claim 14, wherein the pressure sensor includes a second half bridge circuit.

19. The control method of claim 18, wherein the supplying of the reverse bias voltage includes supplying the reverse bias voltage to the first half bridge circuit or not supplying the bias voltage to the first half bridge circuit in a time duration in which pressure sensing using the first half bridge circuit is not performed, and supplying the reverse bias voltage to the second half bridge circuit or not supplying the bias voltage to the second half bridge circuit in a time duration in which pressure sensing using the second half bridge circuit is not performed.

20. The control method of claim 12, wherein the supplying of the forward bias voltage and the supplying of the reverse bias voltage or not supplying of the bias voltage is alternately repeated.
